(19) United States
(12) Patent Application Publication
(10) Pub. No.: US 2005/0142804 A1
(43) Pub. Date: Jun. 30, 2005

(54) Method for fabricating shallow trench isolation structure of semiconductor device

(75) Inventor: Moon Jung Shin, Seongnam-si (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,917

(22) Filed: Dec. 30, 2004

(30) Foreign Application Priority Data
Dec. 30, 2003 (KR) 10-2003-0100538

(51) Int. Cl. H01L 21/8242; H01L 21/76

(52) U.S. Cl. 438/424; 438/427; 438/435; 438/437

(57) ABSTRACT

A method for fabricating a shallow trench isolation structure of semiconductor device is disclosed. The method for fabricating a shallow trench isolation structure of semiconductor device comprises growing a silicon oxide layer on a substrate, depositing a nitride layer with a predetermined thickness and growing a thermal oxide layer as a hard mask to dry-etch a substrate; forming a photoresist pattern through a photolithographic process and dry-etching the thermal oxide layer, the nitride layer and the silicon oxide layer to form a hard mask; removing the photoresist pattern through an ashing/strip process, depositing a layer for forming spacers as thick as critical dimension and pullback targets in order to compensate the regions made by a phosphoric acid strip process and etching the layer for forming spacers; forming silicon trenches using the spacers and the thermal oxide layer deposited on the spacers and the nitride layer; filling an oxide material into the substrate comprising the trenches to form field regions; performing a CMP process for planarizing the silicon nitride layer and the oxide material; and forming active regions and field regions by tuning the ratio of the height of the field region to that of the active region through an oxide layer wet etching process and a phosphoric acid strip process, and by removing the silicon nitride layer, the silicon oxide layer and the spacers.

### BACKGROUND OF THE INVENTION

1. Field of the Invention

The present disclosure relates to a method for fabricating a shallow trench isolation structure of semiconductor device and, more particularly, to a method for fabricating the shallow trench isolation structure by forming spacers with dry etching instead of performing a pullback process with a phosphoric acid strip process, thereby simplifying processes and reducing amounts of particles generated from etching processes.

2. Background of the Related Art

According to the conventional method, a pad oxide layer is grown on a substrate to release the stress of a silicon nitride layer. The silicon nitride is then deposited on the pad oxide layer. Next, an oxide layer is then formed on the silicon nitride layer. The oxide layer is used as an etching mask for forming trenches. A photoresist pattern is then formed on the oxide layer. The trenches are then formed in a substrate through an etching process. A pullback process is then performed to avoid the formation of divots and to insure the width of active regions. Field regions are then filled with an oxide material. Next, active regions and field regions are formed through a Chemical Mechanical Polishing (hereinafter referred to as “CMP”) process.

FIG. 1 illustrates a flowchart according to a conventional method of fabricating a shallow trench isolation structure of semiconductor device.

FIG. 2a through FIG. 2h illustrate, in cross-sectional side views, a conventional method of fabricating a shallow trench isolation structure of semiconductor device.

Referring to FIG. 2a, a silicon oxide layer 1 is deposited on a substrate. The silicon oxide layer 1 is used as a buffer layer. A silicon nitride layer 2 is then deposited on the oxide layer with a predetermined thickness. A thermal oxide layer 3 is then grown on the nitride layer. The thermal oxide layer 3 is used as a hard mask during a dry etching process (S101).

Referring to FIG. 2b, a photoresist pattern 4 is formed on the thermal oxide layer 3. Then, a dry ething process is performed using the photoresist pattern as a mask to remove some parts of the silicon oxide layer, the silicon nitride layer and the thermal oxide layer (S102).

Referring to FIG. 2c, the residuals of the photoresist pattern 4 is removed through an oxygen plasma ashing process (S103).

Referring to FIG. 2d, trenches 5 are formed in the substrate by dry etching with the thermal oxide layer 3 and the silicon nitride layer 2 as a buffer (S104).

Referring to FIG. 2e, a pullback process is performed for the trenches 5 by a phosphoric acid strip process (S105).

Referring to FIG. 2f, an oxide material 7 is deposited over the resulting substrate to form field regions after the pullback process. (S106)

Referring to FIG. 2g, a CMP (Chemical Mechanical Polishing) process is performed to planarize the resulting substrate (S107).

Referring to FIG. 2h, the ratio of the height of the field region to that of the active region is tuned by an oxide layer wet etching process and a phosphoric acid strip process. The silicon nitride layer 2 and the silicon oxide layer 1 used as a buffer are then removed. Finally, the active regions and the field regions are completed (S108).

U.S. Pat. No. 6,291,312, Chan et al., discloses a method for forming a pullback opening above a shallow trench isolation structure.

However, the above-mentioned methods for fabricating a shallow trench isolation structure of semiconductor device have several problems as below.

First, a phosphoric acid strip process for forming pullback regions uses dip type etching in a wet bath. Here, the high temperature of the wet bath may cause defects (i.e., diminish yield). To eliminate the defects, additional processes such as tuning the edge exclusion in a photolithographic process are required. Second, non-uniformity in batch and distribution issues in a wafer can cause serious defects in semiconductor devices as well.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 illustrates a flowchart according to a conventional method of fabricating a shallow trench isolation structure of semiconductor device.

FIGS. 2a through 2h illustrate, in cross-sectional views, a conventional method of fabricating a shallow trench isolation structure of semiconductor device.

FIG. 3 illustrates the flowchart of a method of fabricating a shallow trench isolation structure of semiconductor device according to the present invention.

FIGS. 4a through 4h illustrate, in cross-sectional views, the process of fabricating a shallow trench isolation structure of semiconductor device according to the present invention.

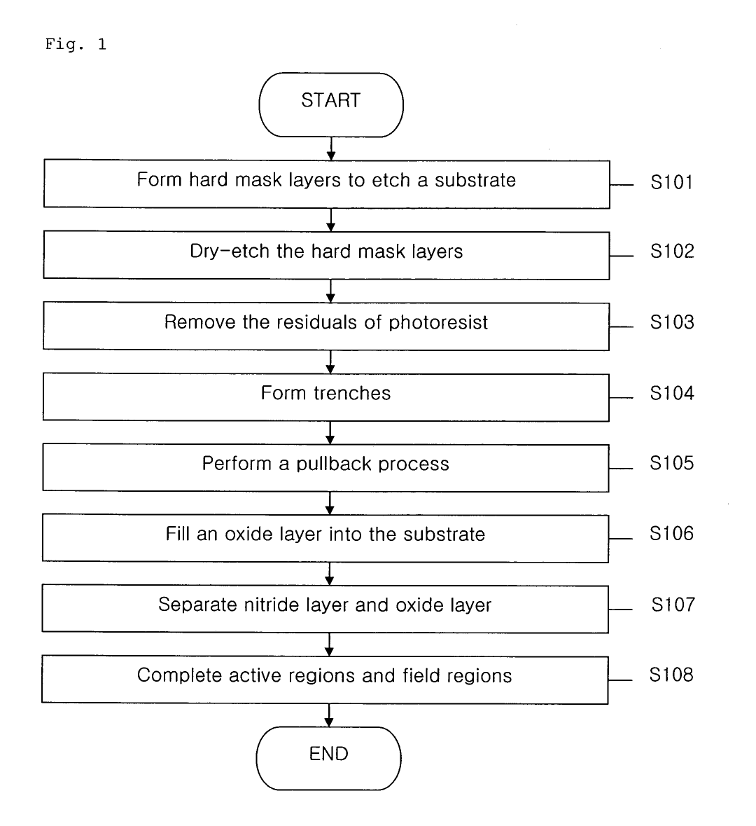

### DETAILED DESCRIPTION OF THE PREFERRED EMBODIMENT

Accordingly, the present invention is directed to a method for fabricating a shallow trench isolation structure of semiconductor device that substantially obviates one or more problems due to limitations and disadvantages of the related art.

An object of the present invention is to achieve a pullback effect by using dry etching instead of wet etching, thereby avoiding risk such as yield loss or needs for additional processes required in the conventional pullback process to form an active region.

In addition, another object of the present invention is to obtain the effect of a phosphoric acid strip process and to insure the margin of critical dimension simultaneously by forming spacers. Here, the formation of the spacers overcomes the limitation of the critical dimension due to exposure limitation. To achieve this object and other advantages and in accordance with the purpose of the invention, as embodied and broadly described herein, the present invention provides a method for fabricating a shallow trench isolation structure of semiconductor device comprising steps of growing a silicon oxide layer on a substrate, depositing a nitride layer with a predetermined thickness and growing a thermal oxide layer as a hard mask to dry-etch a substrate; forming a photoresist pattern through a photolithographic process and dry-etching the thermal oxide layer, the nitride layer and the silicon oxide layer to form a hard mask; removing the photoresist pattern through an ashing/strip process, depositing a layer for forming spacers as thick as critical dimension and pullback targets in order to compensate the regions made by a phosphoric acid strip process and etching the layer for forming spacers; forming silicon trenches using the spacers and the thermal oxide layer deposited on the spacers and the nitride layer; filling an oxide material into the substrate comprising the trenches to form field regions; performing a CMP process for planarizing the silicon nitride layer and the oxide material; and forming active regions and field regions by tuning the ratio of the height of the field region to that of the active region through an oxide layer wet etching process and a phosphoric acid strip process, and by removing the silicon nitride layer, the silicon oxide layer and the spacers.

It is to be understood that both the foregoing general description and the following detailed description of the present invention are exemplary and explanatory and are intended to provide further explanation of the invention as claimed.

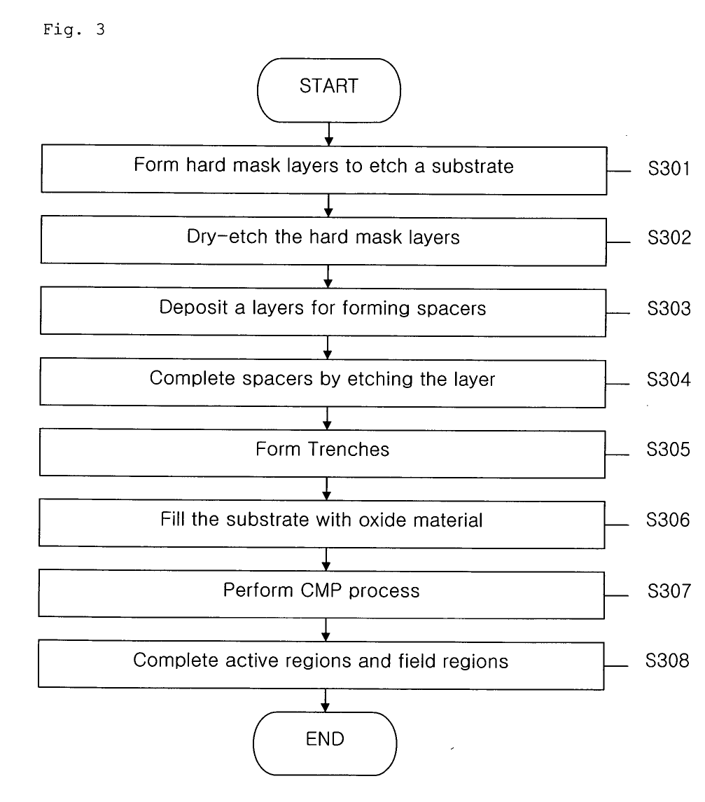

FIG. 3 illustrates the flowchart of a method of fabricating a shallow trench isolation structure of semiconductor device according to the present invention.

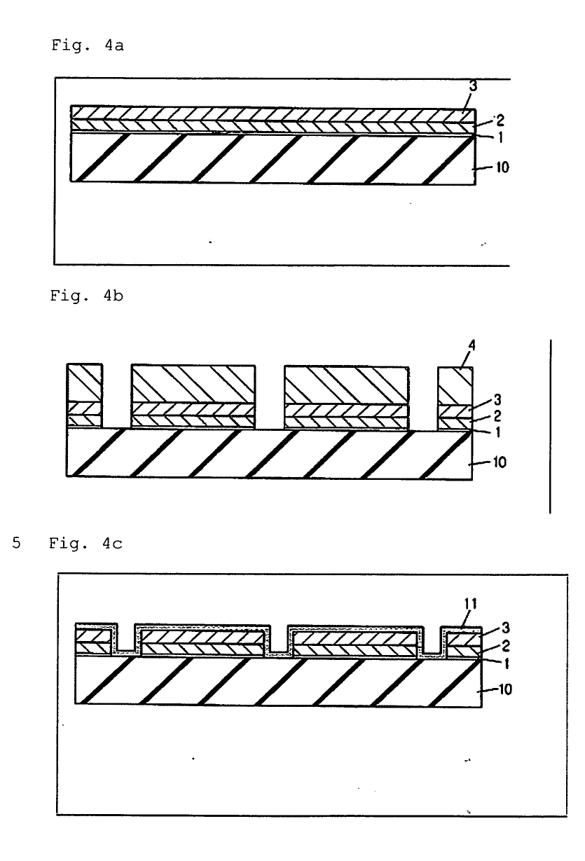

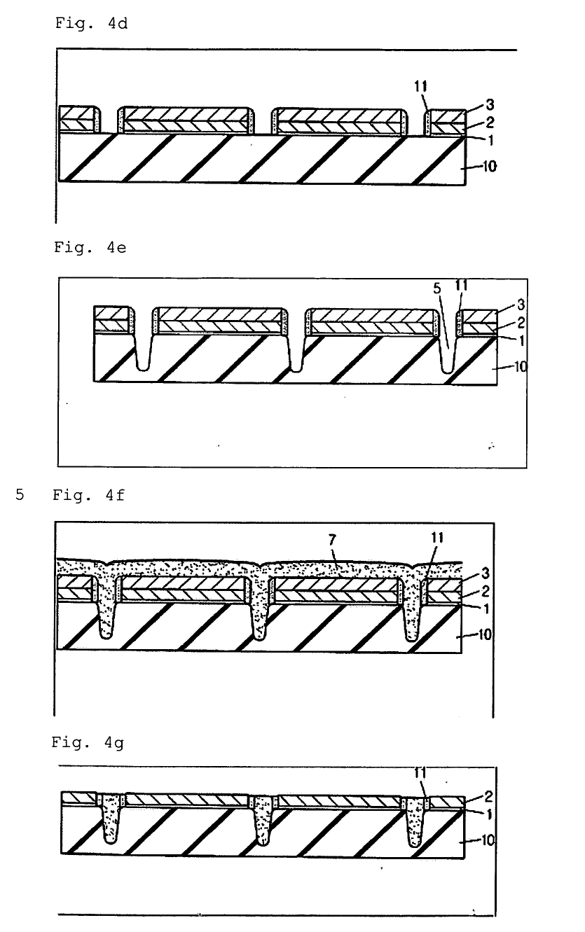

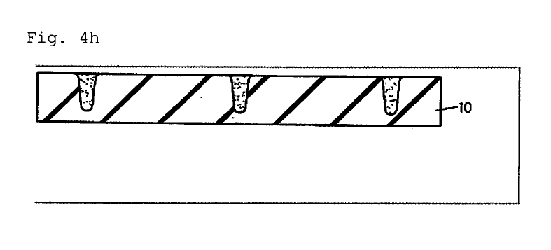

FIGS. 4a through 4h illustrate, in cross-sectional views, the process of fabricating a shallow trench isolation structure of semiconductor device according to the present invention.

Referring to FIG. 4a, a silicon oxide layer 1 for a buffer layer is grown on a substrate 10. A silicon nitride layer 2 is then formed on the silicon oxide layer 1 with a predetermined thickness. A thermal oxide layer 3 is then formed on the nitride layer 2. The thermal oxide layer 3 is used as a hard mask for etching the substrate 10(S301).

Referring to FIG. 4b, a photoresist pattern 4 is formed on the thermal oxide layer 3. Next, the dry-etching process is performed using the photoresist pattern 4 to remove some parts of the silicon oxide layer 1, the silicon nitride layer 2 and the thermal oxide layer 3 (S302).

Referring to FIG. 4c, the photoresist pattern 4 is removed through an ashing strip process. A layer for forming spacers 11 is then deposited to compensate the regions made by a phosphoric acid strip process. Here, the thickness of the layer for forming spacers needs to comply with the critical dimension and that of the pullback target (S303).

Referring to FIG. 4d, the layer for forming spacers 11 is etched. Here, the amount to be etched is dependent on per-side amount as well as the pullback target. Spacers are then completed (S304).

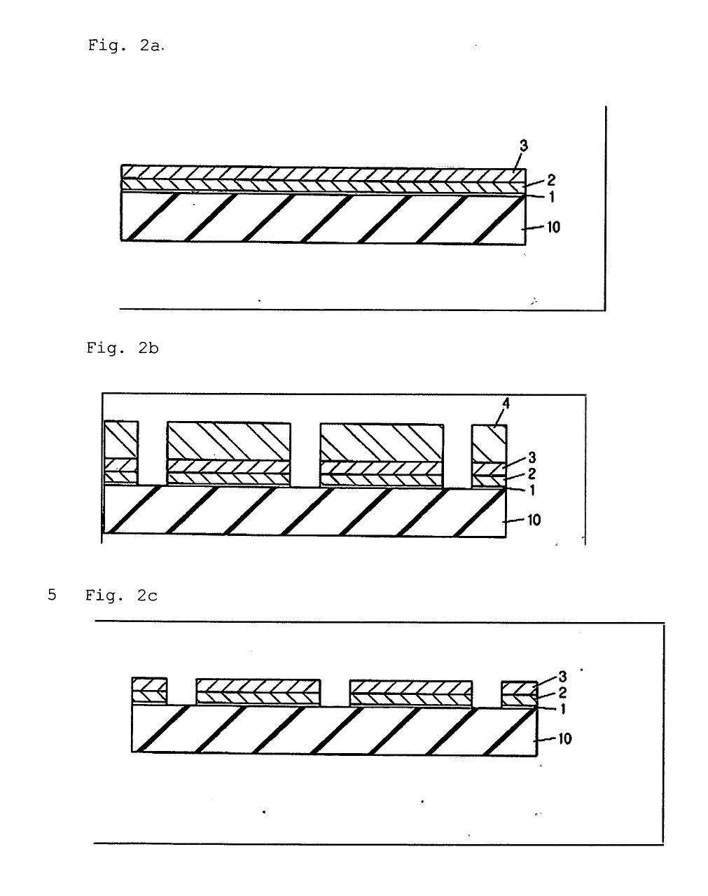

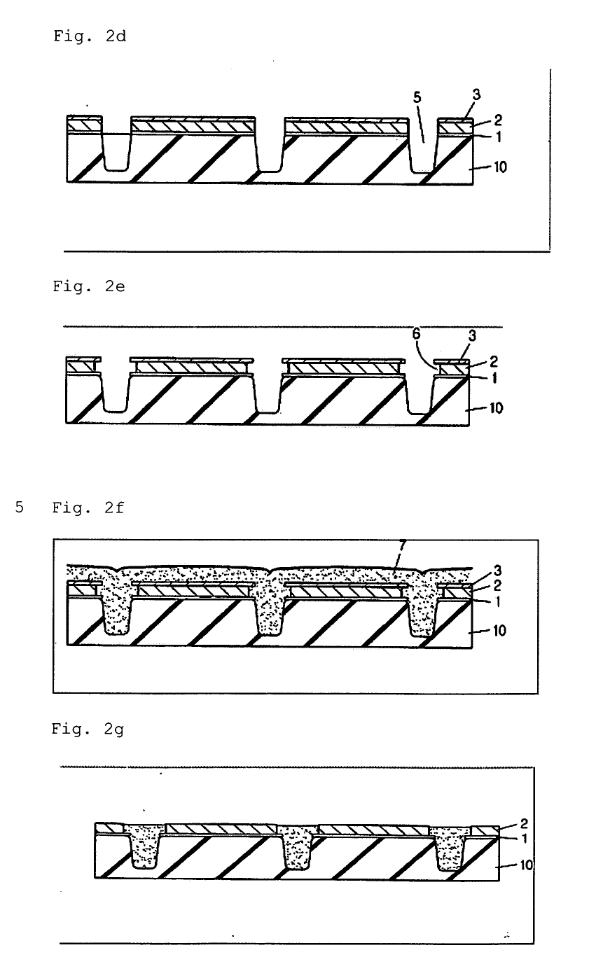

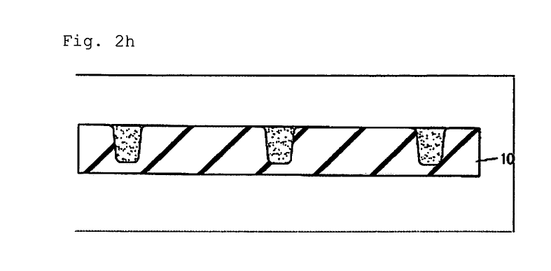

Referring to FIG. 4e, trenches are formed using the spacers 11 and the thermal oxide layer 3 deposited on the spacers 11 and the silicon nitride layer 2. In comparison to FIG. 2e according to the prior art, the undercut region of the silicon nitride layer 2 is obtained without any additional process (S305).

Referring to FIG. 4f, an oxide material 7 is then deposited all over the substrate including the trenches (S306) to form field regions.

Referring to FIG. 4g, a CMP (Chemical Mechanical Polishing) process is then performed to planarize the resulting substrate including the oxide material 7 and the nitride layer 2. (S307)

Referring to FIG. 4h, the ratio of the height of the field region to that of the active region is tuned by an oxide wet etching process and a phosphoric acid strip process. The silicon nitride layer 2 and the silicon oxide layer 1 used as a buffer and spacers 11 are then removed. The active regions and the field regions are completed (S308).

Accordingly, the present invention achieves the effect of a phosphoric acid strip process by performing the spacer process for insuring the margin of the critical dimension. After the oxide layer and the nitride layer are deposited, spacers are formed and etched in order to overcome the limitation of the critical dimension due to exposure limitation and to achieve the effect of the phosphoric acid strip process simultaneously. Moreover, the present invention can omit the dip type process such as the phosphoric acid process and, therefore, avoid the defect that the irregular flow of phosphoric acid solution around the wafer edge would cause, thereby improving yield.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A method for fabricating a shallow trench isolation structure of semiconductor device comprising the steps of:
(a) growing a silicon oxide layer on a substrate, depositing a nitride layer with a predetermined thickness and growing a thermal oxide layer as a hard mask to dry-etch a substrate;
(b) forming a photoresist pattern through a photolithographic process and dry-etching the thermal oxide layer, the nitride layer and the silicon oxide layer to form a hard mask;
(c) removing the photoresist pattern through an ashing/strip process, depositing a layer for forming spacers as thick as critical dimension and pullback targets in order to compensate the regions made by a phosphoric acid strip process and etching the layer for forming spacers;
(d) forming silicon trenches using the spacers and the thermal oxide layer deposited on the spacers and the nitride layer;
(e) filling an oxide material into the substrate comprising the trenches to form field regions;
(f) performing a CMP process for planarizing the silicon nitride layer and the oxide material; and
(g) forming active regions and field regions by tuning the ratio of the height of the field region to that of the active region through an oxide layer wet etching process and a phosphoric acid strip process, and by removing the silicon nitride layer, the silicon oxide layer and the spacers.

2. The method as defined by claim 1, wherein the etching in the step (c) is dry etching.

3. The method as defined by claim 1, wherein the step (c) insures undercut regions by only depositing and etching the spacers.

4. The method as defined by claim 1, the spacers substitute the functions of a phosphoric acid strip process in order to insure the margin of critical dimension.
